(19) United States
(12) Patent Application Publication
(10) Pub. No.: US 2010/0028813 A1
(43) Pub. Date: Feb. 4, 2010

(54) BACKSIDE CLEANING OF SUBSTRATE

(76) Inventors: Banqiu Wu, Sunnyvale, CA (US); Ajay Kumar, Cupertino, CA (US); Amitabh Sabharwal, San Jose, CA (US); Roman Gouk, San Jose, CA (US); James S. Papanu, San Rafael, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/185,595

(22) Filed: Aug. 4, 2008

(51) Int. Cl. G03F 7/20; B08B 13/00; B08B 7/00; B08B 3/12

(52) U.S. Cl. 430/322; 134/201; 134/42; 134/1

(57) ABSTRACT

A pellicle cover, system, and method for cleaning a photomask are disclosed. A pellicle cover is disposed over a photomask and pellicle without damaging the markings surrounding the mask pattern area. The pellicle cover can be practicably implemented in an improved photomask cleaning system and process in which the backside of the photomask may be cleaned without removing the pellicle from the patterned surface.

### BACKGROUND

1. Field

Embodiments of the present invention relate to the field of semiconductor processing and manufacturing. More particularly embodiments of this invention relate to the area of cleaning a substrate such as photomask.

2. Background Information

Photolithography is well established in the manufacture of semiconductor devices. As device size continues to shrink, finer pitch size and precision is required during photolithography patterning. These requirements are even more stringent with substrates such as photomasks. For instance, it is of utmost importance that the pattern of a photomask remain particle free because particles on the photomask pattern can scatter photolithographic wavelengths resulting in compromised fidelity and contrast of the reproduced image.

It is therefore common practice that the photomask pattern area be covered by a pellicle to shield from particles being disposed on the pattern. A typical pellicle includes a pellicle frame made from a rigid material such as aluminum and a pellicle membrane made from a thin, highly transparent film such as a polymeric resin. The pellicle membrane is spread over and adhesively bonded to the pellicle frame in a drumhead-like slack-free fashion. The other end of the pellicle frame is also adhesively bonded to the top surface of the photomask containing the pattern.

While the pellicle is useful for protecting the photomask pattern area, the backside of the photomask is often in contact with various vacuum chucks during handling. As a result, the backside of the photomask becomes contaminated with particles which can lead to refraction problems during photolithography.

Conventional cleaning techniques require cleaning one side of the photomask at a time, which also requires removing the pellicle. This is of particular concern because the adhesive which is conventionally used to secure the pellicle frame to the photomask is difficult to remove. Any amount of adhesive contamination in the photomask pattern can be ruinous to the entire photomask.

### SUMMARY

Embodiments of the present invention disclose a pellicle cover which can be practicably implemented in an improved photomask cleaning system and process in which the backside of the photomask may be cleaned without removing the pellicle from the patterned surface. The pellicle cover can be disposed over the pellicle surrounding the pattern area, and additional markings located outside of the pellicle so that the fragile features on the photomask surface are not damaged.

### BRIEF DESCRIPTION OF THE DRAWINGS

FIG. 1 is a top view illustration of a conventional photomask.

FIG. 2 is a side view illustration of a photomask cleaning system.

FIG. 3A and FIG. 3B are top view and isometric view illustrations of a pellicle cover resting on a portion of a photomask.

FIG. 4A and FIG. 4B are top view and isometric view illustrations of a pellicle cover resting on a holding bracket finger.

FIG. 5 is an illustration of a method of cleaning a photomask.

### DETAILED DESCRIPTION

Embodiments of the present invention disclose a pellicle cover, system, and method for cleaning a substrate such as a photomask.

Various embodiments described herein are described with reference to figures. However, certain embodiments may be practiced without one or more of these specific details, or in combination with other known methods and configurations. In the following description, numerous specific details are set forth, such as specific configurations, compositions, and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment” or “an embodiment” means that a particular feature, configuration, composition, or characteristic described in connection with the embodiment is included in at least one embodiment of the invention. Thus, the appearances of the phrase “in one embodiment” or “an embodiment” in various places throughout this specification are not necessarily referring to the same embodiment of the invention. Furthermore, the particular features, configurations, compositions, or characteristics may be combined in any suitable manner in one or more embodiments.

In one aspect, embodiments of the invention allow for cleaning a photomask without having to remove a pellicle. In an embodiment, a pellicle cover is disposed over the pellicle without touching the thin pellicle membrane. The pellicle cover protects the pellicle membrane from liquid and mist that could otherwise deposit onto the pellicle membrane during cleaning.

In another aspect, embodiments of the invention disclose a pellicle cover disposed over a top surface of a photomask including a pattern area and additional marks located outside of the pattern area. In this manner, the pellicle cover does not cause damage to fragile structures on the top surface of the photomask. Furthermore, the pellicle cover may be temporary and reused with photomasks made by different manufacturers. The pellicle cover can be practicably employed in a large scale process for cleaning multiple photomasks made by various manufacturers which implement markings such as fiducials, an internal identification mark, and internal reference marks in different locations.

In another aspect, embodiments of the invention disclose a cleaning method in which a pellicle cover is disposed over a photomask and pellicle without becoming a source of contamination itself. For example, the pellicle cover may be disposed over the photomask and pellicle without the use of adhesives or other organics.

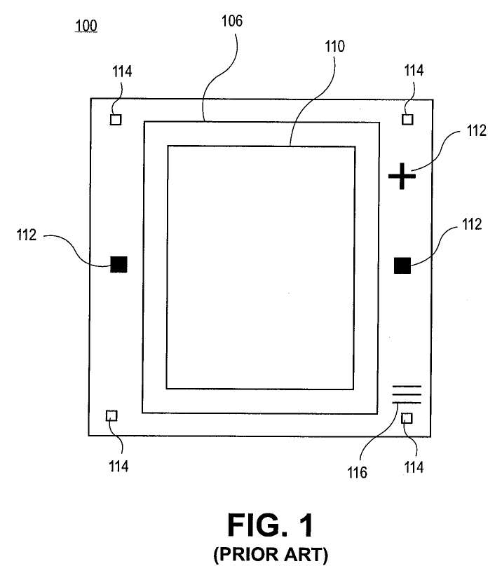

FIG. 1 is a top view illustration of a conventional photomask 100. As shown in FIG. 1, a top surface of a conventional photomask 100 includes a mask pattern area 110. For example, the mask pattern area 110 may include a portion of an integrated circuit design to be used in patterning a silicon wafer. In an exemplary 6×6 inch photomask the pattern area is 104×132 mm approximately centered on the top surface of the photomask. The top surface may further comprise one or more fiducials 112, which are typically patterns located outside the pattern area 110 used to align different layers to one another during photolithographic exposure operations. Different manufacturers of photomasks, as well as photolithographic stepper models, may have different types and placements of fiducials. The top surface may further comprise an internal identification mark 116 and/or one or more internal reference marks 114. Internal identification mark 116 may be used by a customer internally to identify the mask pattern. Internal reference marks 114 may be used as points of reference when setting up inspections on an inspection system and when repairing defects found in such inspections. The design and placement of these internal marks may vary from one manufacturer and customer to another.

A pellicle 106 may be attached to the photomask 100 to protect the mask pattern area 110. A pellicle 106 may comprise a variety of components and be attached in a variety of manners. In an embodiment, the pellicle 106 surrounds the mask pattern area 110 but does not surround markings outside of the pattern area 110 such as fiducials 112, internal identification mark 116 or internal reference marks 114. In an embodiment, the pellicle is adhesively attached to the photomask 100.

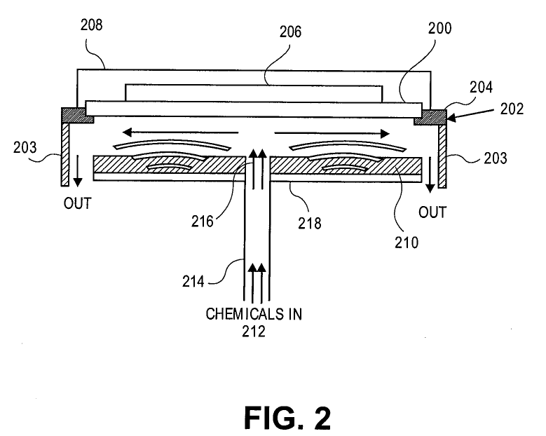

FIG. 2 is a side view illustration of an embodiment of a system for cleaning a photomask. As shown in FIG. 2, a rotatable holding bracket 202 supports photomask 200. In an embodiment, the holding bracket 202 comprises a set of fingers 204 attached to a chuck (not shown) via support posts 203. In a specific embodiment, the holding bracket 202 comprises a set of four mask holder fingers 204 designed to support a square photomask at the four respective corners. In alternative embodiments, the photomask can be shaped other than square, such as circular. Additionally, the holding bracket 202 can comprise three or more holder fingers 204, or alternatively a continuous shelf for supporting a photomask.

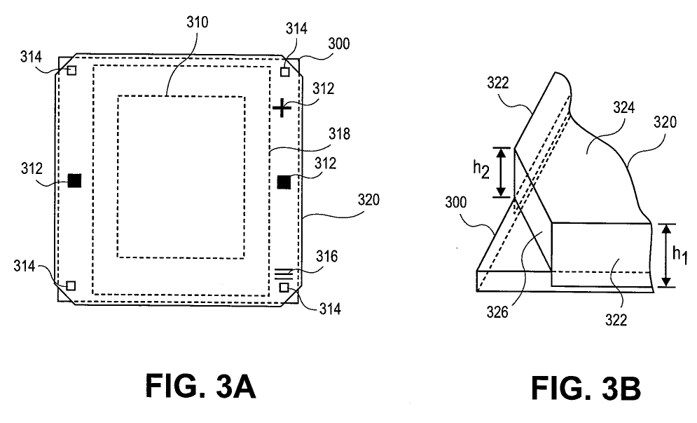

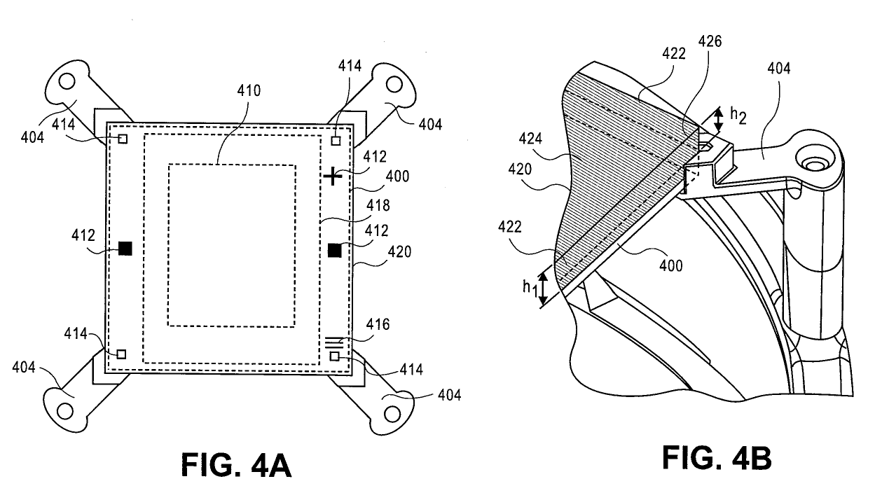

A pellicle 206 is attached to the top surface of the photomask 200 and surrounding the pattern area as described in relation to FIG. 1. A pellicle cover 208 (described in more detail in FIG. 3A-FIG. 4B and annotated as 320 and 420) is disposed over the top surface of the photomask 200 and surrounding the pellicle 206, as shown in FIG. 2. The pellicle cover can be formed from a variety materials including plastics such as polyvinyl chloride (PVC) and polytetrafluoroethylene (PTFE). In an embodiment, the pellicle cover is contamination-free and does not generate contamination during use. In an embodiment, the pellicle cover is free of surface particles having a particle size greater than 50 nm. Herein, the term “particle size” is determined on a volume based diameter called “polystyrene latex (PSL) equivalent size.”

In an embodiment, the pellicle cover 208 also surrounds other markings outside of the pellicle 206 such as fiducials, an internal identification mark or internal reference marks on the top surface of the photomask 200. In an embodiment, the pellicle cover 208 is disposed without the use of adhesives. In an embodiment, the pellicle cover 208 rests on portions of the photomask 200 or holding bracket 202, and is secured through gravitational and centripetal forces while the holding bracket 202 and photomask 200 are rotated. In an alternative embodiment, the pellicle cover 208 is secured by mechanical clamping, screws, or clips.

A platter 210 is located below the photomask 200. The vertical positions of the platter 210 and holding bracket 202 can be adjusted in order obtain an optimal distance between the photomask 200 and platter 210. The top surface of the platter 210 is flat where it faces the photomask 200 and therefore the distance separating the platter 210 and photomask 200 is uniform. The gap may be in the range of approximately 1-5 mm and preferably approximately 3 mm. In an embodiment, the top surface of the platter 210 may include a dished out portion (not shown).

Chemicals 212 can be dispensed from below to contact the photomask backside. A tube 214 connects to a through hole (feed port) 216 in the platter 210. When the photomask 200 is spun, the chemicals 212 applied to the photomask backside are restricted from reaching the top side of the photomask by centripetal forces. The pellicle cover 208 additionally provides protection from any chemicals or mist that could splash or other otherwise deposit on to the membrane of pellicle 206. Accordingly, it is not necessary to form a tight seal between the pellicle cover 208 and the photomask 200.

The bottom side of the platter 210 may have a transducer 218 attached. In an embodiment, the transducer is a single plate. In another embodiment, multiple transducers are attached. The transducer(s) 218 can generate frequencies in the range of, for example, between 350 kHz to 10 MHz.

FIG. 3A and FIG. 3B are illustrations of an embodiment where the pellicle cover rests on a portion of the photomask. As shown in FIG. 3A, a pellicle cover 320 is disposed over a photomask 300 and pellicle 318. The photomask 300 may include a pattern area 310 inside the pellicle 318. The photomask 300 may further include markings outside of the pellicle 318 and pattern area 310 such as fiducials 312, internal identification mark 316 and internal reference marks 314. In an embodiment, the pellicle cover 320 is disposed over and surrounding the fiducials 312, internal identification mark 316 and internal reference marks 314. It is understood that some photomask markings (312, 314, 316) may be placed very near the edges of the photomask. Accordingly, in an alternative embodiment, the pellicle cover 320 is disposed over and surrounding substantially all or a substantial portion of the markings (312, 314, 316) located outside the pellicle 318 and pattern area 310. In an embodiment, the pellicle cover 320 is disposed over and surrounding all markings (312, 314, 316) except those positioned within a few mm of the corners of the photomask 300.

FIG. 3B is an isometric view illustration of FIG. 3A. As shown in FIG. 3B, the pellilcle cover 320 includes sidewalls 322 having a height h1 extending from a top pellicle surface 324. The pellicle cover 320 additionally includes sidewall corner regions 326 having a second height h2 extending from the top pellicle surface 324. In an embodiment the second height h2 is less than height h1. As shown in FIG. 3B, the corner regions 326 can be beveled and rest on the top surface of the photomask 300 while the sidewalls 322 do not rest on the top surface of the photomask 300. In an embodiment the sidewalls 322 extend at least partially down the thickness of the photomask 300. As shown in FIG. 3B, the beveled corner region 326 can comprise a flat surface that does not form a right angle with the two adjoining sidewalls 322. Alternatively, the corner region 326 can comprise a rounded surface adjoining the two sidewalls 322, or multiple surfaces adjoining the two sidewalls 322. In an embodiment, the pellicle cover 320 is secured through gravitational and centripetal forces while the holding bracket and photomask are rotated. The sidewalls 322 extending at least partially down the thickness of the photomask 300 help secure the pellicle cover 320 to the photomask 300 during rotation. In an alternative embodiment, the pellicle cover 320 is secured to the photomask 300 by mechanical clamping, screws, or clips.

FIG. 4A and FIG. 4B are illustrations of an embodiment where the pellicle cover rests on the holding bracket fingers and does not rest on a portion of the photomask. As shown in FIG. 4A, a pellicle cover 420 is disposed over a photomask 400 and pellicle 418. The photomask 400 may include a pattern area 410 inside the pellicle 418. The photomask 400 may further include markings outside of the pellicle 418 and pattern area 410 such as fiducials 412, internal identification mark 416 and internal reference marks 414. In an embodiment, the pellicle cover 420 is disposed over and surrounding all photomask markings (412, 414, 416) including those placed very near the edges of the photomask. Thus, a particular advantage of such an embodiment is that the risk of damaging any fragile features on the photomask 400 top surface (which can also serve as a contamination source) is eliminated.

FIG. 4B is an isometric view illustration of FIG. 4A. As shown in FIG. 4B, the pellicle cover 420 includes sidewalls 422 having a height h1 extending from a top pellicle surface 424. In an embodiment, portions of the sidewalls 422 extend at least partially down the thickness of the photomask 400. The pellicle cover 420 additional includes sidewall corner regions 426 having a second height h2 extending from the top pellicle surface 424. In an embodiment, the second height h2 is less than height h1. As shown in FIG. 3B, the corner region 426 is a part of the two adjoining sidewalls 422 and designed to rest on and/or against holder fingers 404. In an alternative embodiment, corner regions 426 have the same height h2 as the sidewall height h2. Corner regions 426 can be configured to rest on the holder fingers 404 in positions different than the particular position shown in FIG. 4B. In an embodiment, the pellicle cover 420 is secured through gravitational and centripetal forces while the holding bracket and photomask are rotated. The sidewall portions 422 extending at least partially down the thickness of the photomask 400 and/or resting against the holder fingers 404 help secure the pellicle cover 420 to the photomask 400 during rotation In an alternative embodiment, the pellicle cover 420 is secured to the holder fingers 404 by mechanical clamping, screws, or clips.

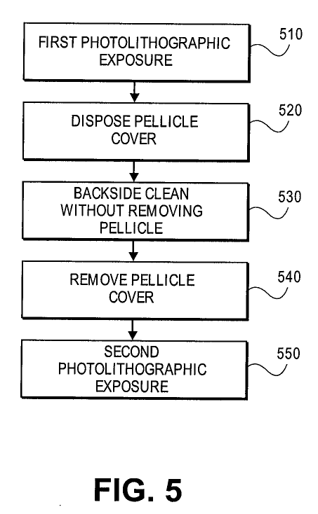

FIG. 5 is an illustration of an embodiment for method of cleaning a photomask. As shown in FIG. 5, a photomask is exposed to a first wavelength in a photolithographic operation 510. In an embodiment, the photomask includes a pattern area and additional markings on the top surface such as fiducials, an internal identification mark, and/or internal reference marks. A pellicle is disposed over the top surface and surrounding the pattern area. A pellicle cover is then disposed over the photomask and pellicle at operation 520. In an embodiment, the pellicle cover surrounds the pellicle and additional markings on the photomask top surface located outside of the pellicle. In an embodiment, the pellicle cover rests on the portions of the photomask (as described in relation to FIG. 3A-3B) or holding bracket (as described in relation to FIG. 4A-4B). In an embodiment, the pellicle cover is disposed without the use of adhesives. In an embodiment, the pellicle cover is secured through gravitational and centripetal forces while the holding bracket and photomask are rotated. In an alternative embodiment, the pellicle cover is secured by mechanical clamping, screws, or clips.

A cleaning operation is then performed at operation 530 without removing the pellicle cover 208. In an embodiment, a back side cleaning operation is performed while rotating the photomask. A cleaning chemical 212 such as ozonated DI water, ammonium, and/or organic solvents is flowed through tube 214 and out through hole 216 to contact the backside of photomask 200. It is preferable to not employ cleaning chemicals associated with haze issues, such as sulfuric acid. In an embodiment, the ozonated DI water is supplied at a flow rate of 1 liter per minute for approximately 10-20 minutes while spinning the photomask 200 at a rate of approximately 50-300 RPM, and more specifically 75-150 RPM. The flow of the cleaning chemical is then stopped and the backside of photomask 200 is then rinsed. A rinse chemical 212 such as DI water may be flowed through tube 214 and out through hole 216 to contact the backside of the photomask 200 while rotating the photomask 200 at a rate of approximately 50-300 RPM, and more specifically 75-150 RPM. Megasonic energy can be applied during application of the cleaning chemical, DI rinse, or both. The pellicle cover 208 is then removed at operation 540, and the photomask is then exposed to a wavelength in a second photolithographic operation 550.

In the foregoing specification, various embodiments of the invention have been described. A pellicle cover may be temporarily disposed over a first photomask so that the photomask may be cleaned without removing the attached pellicle. The pellicle cover may then be removed from the first photomask, cleaned, and then temporarily disposed over a second photomask so that the second photomask may be cleaned without removing the attached pellicle. Utilizing the various embodiments of the invention the pellicle cover may be practicably employed in a large scale process for cleaning photomasks made by various manufacturers which implement markings in different locations. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A system for cleaning a photomask comprising:
a bracket supporting a photomask having a pattern area and other markings outside of the pattern area on a top surface of the photomask;
a pellicle disposed on the top surface and surrounding the pattern area;
a pellicle cover disposed over the pellicle and other markings outside the pattern area.

2. The system of claim 1, wherein the pellicle cover is disposed over the top surface without an adhesive.

3. The system of claim 2, wherein the pellicle cover includes sidewalls having a first height extending from a pellicle top surface, and sidewall corner regions having a second height extending from the pellicle top surface, wherein the second height is less than the first height.

4. The system of claim 3, wherein the pellicle cover rests on the bracket, and the pellicle cover does not rest on the top surface of the photomask.

5. The system of claim 3, wherein the sidewall corner regions are beveled and rest on the top surface of the photomask.

6. The system of claim 3, further comprising a platter and megasonic transducer positioned below the photomask.

7. The system of claim 6, wherein the platter comprises a through hole for delivering a liquid between the platter and photomask.

8. A pellicle cover comprising:
a top surface,
sidewalls having a first height extending from the top surface, and
sidewall corner regions having a second height extending from the top surface, wherein the second height is less than the first height;
wherein the pellicle cover is free of surface particles having a particle size greater than 50 nm.

9. The pellicle cover of claim 8, wherein the sidewall corner regions are beveled.

10. The pellicle cover of claim 9, wherein the beveled sidewall corner regions include a surface that does not form a right angle with two adjoining sidewalls.

11. The pellicle cover of claim 9, wherein the beveled sidewall corner regions include a rounded surface adjoining two sidewalls.

12. The pellicle cover of claim 9, wherein the sidewall corner regions are designed to rest on a photomask top surface.

13. The pellicle cover of claim 8, wherein the sidewall corner regions are a part of two adjoining sidewalls.

14. The pellicle cover of claim 13, wherein the sidewall corner regions are designed to rest on photomask support fingers.

15. A method comprising:
disposing a pellicle cover over a photomask and pellicle, the photomask having a top surface and a back side, the top surface including a pattern area and additional markings, and a pellicle attached to the top surface and surrounding the pattern area, wherein the additional markings are located outside of the pellicle and pattern area; and
cleaning the back side of the photomask.

16. The method of claim 15, further comprising removing the pellicle cover after cleaning the back side of the photomask.

17. The method of claim 16, further comprising:
exposing a photomask to a first photolithographic exposure prior to disposing the pellicle cover over the photomask and pellicle;
exposing a photomask to a second photolithographic exposure after removing the pellicle cover.

18. The method of claim 15, wherein cleaning the back side of the photomask comprises applying megasonic energy from the back side of the photomask.

19. The method of claim 15, wherein the pellicle cover is disposed over the photomask and pellicle without the use of an adhesive.

20. The method of claim 16 further comprising disposing the pellicle cover over a second photomask and second pellicle.
